(19) United States
(12) Patent Application Publication
(10) Pub. No.: US 2024/0275346 A1
(43) Pub. Date: Aug. 15, 2024

(54) OUTPHASING AMPLIFIER AND METHOD OF MANUFACTURING THE SAME

(71) Applicant: Sumitomo Electric Industries, Ltd., Oska (JP)

(72) Inventor: Takashi SUMIYOSHI, Oska-shi (JP)

(73) Assignee: Sumitomo Electric Industries, Ltd., Oska (JP)

(21) Appl. No.: 18/499,498

(22) Filed: Nov. 1, 2023

(30) Foreign Application Priority Data
Feb. 13, 2023 (JP) 2023-019713

(51) Int. Cl. H03F 3/60; H03F 1/02; H03F 1/56

(52) U.S. Cl. CPC H03F 3/602; H03F 1/0294; H03F 1/56

(57) ABSTRACT

An outphasing amplifier includes a first amplifier, a second amplifier, and a combiner. The combiner includes a first node inputting a first signal, a second node inputting a second signal, a third node outputting a combined signal as an output signal, a first impedance converter connected to the first node and the third node, a second impedance converter connected to the second node and the third node, a first open stub wherein when an electrical length converted into a phase at a center frequency of an operating frequency band is θ3, and an outphasing angle when a power of the output signal has a minimum value is θbo, θ3 is different from 180°−θbo and +θbo, and a second open stub wherein when an electrical length converted into a phase at the center frequency is θ4, θ4 is different from 180°−θbo and +θbo.

### CROSS REFERENCE TO RELATED APPLICATIONS

This application claims priority based on Japanese Patent Application No. 2023-019713 filed on Feb. 13, 2023, and the entire contents of the Japanese patent applications are incorporated herein by reference.

### FIELD

The present disclosure relates to an outphasing amplifier and a method of manufacturing the same.

### BACKGROUND

An outphasing amplifier is known as an amplifier for amplifying a high frequency signal such as a microwave. The outphasing amplifier includes a signal processor, two amplifiers and a combiner. The signal processor outputs two signals in which an outphasing angle is changed based on an amplitude of an input signal. The two amplifiers amplify two signals output from the signal processor, respectively. The combiner combines the two output signals amplified by the two amplifiers into one output signal. It is known to use a Chireix combiner as a combiner (for example, Patent Document 1: Japanese Laid-open Patent Publication No. 2020-156023).

### SUMMARY

An outphasing amplifier according to the present disclosure includes a first amplifier amplifying a first signal; a second amplifier amplifying a second signal; and a combiner. The combiner includes: a first node to which the first signal amplified by the first amplifier is input; a second node to which the second signal amplified by the second amplifier is input; a third node combining the first signal and the second signal and outputting a combined signal as an output signal; a first impedance converter having a first end connected to the first node and a second end connected to the third node; a second impedance converter having a first end connected to the second node and a second end connected to the third node; a first open stub having a first end connected to the first node and a second end that is opened, wherein when an electrical length of the first open stub converted into a phase at a center frequency of an operating frequency band is θ3, and an outphasing angle when a power of the output signal has a minimum value is θbo, θ3 is different from any of 180°−θbo and +θbo; and a second open stub having a first end connected to the second node and a second end that is opened, wherein when an electrical length of the second open stub converted into a phase at the center frequency is θ4, θ4 is different from any of 180°−θbo and +θbo.

In a method of manufacturing an outphasing amplifier according to the present disclosure, the outphasing amplifier includes: a first amplifier amplifying a first signal; a second amplifier amplifying a second signal; and a combiner. The combiner includes: a first node to which the first signal amplified by the first amplifier is input; a second node to which the second signal amplified by the second amplifier is input; a third node combining the first signal and the second signal and outputting a combined signal as an output signal; a first impedance converter having a first end connected to the first node and a second end connected to the third node; a second impedance converter having a first end connected to the second node and a second end connected to the third node; a first open stub having a first end connected to the first node and a second end that is opened, wherein when an outphasing angle when a power of the output signal has a minimum value is θbo, an electrical length of the first open stub converted into a phase at a center frequency of an operating frequency band is 180°−θbo; and a second open stub having a first end connected to the second node and a second end that is opened, wherein an electrical length of the second open stub converted into a phase at the center frequency is +θbo. The method of manufacturing an outphasing amplifier according to the present disclosure includes: preparing the outphasing amplifier; and adjusting a length of the first open stub and a length of the second open stub such that a first impedance viewed from the first amplifier to the first node and a second impedance viewed from the second amplifier to the second node have values at which characteristics of the first amplifier and the second amplifier are improved.

### BRIEF DESCRIPTION OF DRAWINGS

FIG. 1 is a block diagram illustrating an outphasing amplifier according to a first embodiment.

FIG. 2 is a block diagram illustrating an outphasing amplifier according to the first embodiment.

FIG. 3 is a schematic diagram illustrating vectors of output power in the first embodiment.

FIG. 4 is a schematic diagram illustrating vectors of output power in the first embodiment.

FIG. 5 is a Smith chart illustrating impedances in a first comparative example.

FIG. 6 is a Smith chart illustrating impedances in the first embodiment.

FIG. 7 is a plan view illustrating a Chireix combiner according to the first embodiment.

FIG. 8 is a circuit diagram illustrating an outphasing amplifier according to a second comparative example.

FIG. 9 is a flowchart illustrating a method of designing the outphasing amplifier according to the first embodiment.

FIG. 10 is a Smith chart illustrating impedances Za and Zb in a fundamental wave.

FIG. 11 is a Smith chart illustrating impedances Zc and Zd in the fundamental wave.

FIG. 12 is a diagram illustrating a method of manufacturing the outphasing amplifier according to the first embodiment.

### DETAILED DESCRIPTION OF EMBODIMENTS

In the outphasing amplifier, a harmonic circuit is used to process harmonics. However, the provision of the harmonic circuit increases the size of the outphasing amplifier.

The present disclosure has been made in view of the above problem, and an object of the present disclosure is to provide an outphasing amplifier and a method of manufacturing an outphasing amplifier that can be reduced in size.

### Details of Embodiments of the Present Disclosure

First, the contents of the embodiments of this disclosure are listed and explained.

(1) An outphasing amplifier according to the present disclosure includes a first amplifier amplifying a first signal; a second amplifier amplifying a second signal; and a combiner. The combiner includes: a first node to which the first signal amplified by the first amplifier is input; a second node to which the second signal amplified by the second amplifier is input; a third node combining the first signal and the second signal and outputting a combined signal as an output signal; a first impedance converter having a first end connected to the first node and a second end connected to the third node; a second impedance converter having a first end connected to the second node and a second end connected to the third node; a first open stub having a first end connected to the first node and a second end that is opened, wherein when an electrical length of the first open stub converted into a phase at a center frequency of an operating frequency band is θ3, and an outphasing angle when a power of the output signal has a minimum value is θbo, θ3 is different from any of 180°−θbo and +θbo; and a second open stub having a first end connected to the second node and a second end that is opened, wherein when an electrical length of the second open stub converted into a phase at the center frequency is θ4, θ4 is different from any of 180°−θbo and +θbo. Thus, it is possible to provide an outphasing amplifier that can be reduced in size.

(2) In the above (1), an absolute value of a difference between θ3 and 180°−θbo may be 0.5° or more and 10° or less, and an absolute value of a difference between θ4 and +θbo may be 0.5° or more and 10° or less. Thus, the characteristics of the outphasing amplifier can be improved.

(3) In the above (2), a sign of θ3−(180°−θbo) and a sign of θ4−θbo may be the same as each other. Thus, the characteristics of the outphasing amplifier can be improved.

(4) In the above (3), an absolute value of a difference between θ3−(180°−θbo) and θ2−θbo may be 1° or less. Thus, the characteristics of the outphasing amplifier can be improved.

(5) In any one of the above (1) to (4), the first impedance converter may be a first transmission line whose electrical length is ¼ of a wavelength of the center frequency, and the second impedance converter may be a second transmission line whose electrical length is ¼ of a wavelength of the center frequency. This allows the first transmission line and the second transmission line to function as impedance converters.

(6) In the above (5), the first transmission line, the second transmission line, the first open stub, and the second open stub may be formed by a dielectric layer and a conductor pattern provided on the dielectric layer. This makes it possible to easily adjust the electrical lengths of the first open stub and the second open stub.

(7) In any one of the above (1) to (6), the outphasing amplifier further may include a first matching circuit connected between the first amplifier and the first node, and a second matching circuit connected between the second amplifier and the second node. This makes it possible to match impedances viewed from the first matching circuit to the first node and from the second matching circuit to the second node with impedances at which the first amplifier and the second amplifier operate optimally.

(8) In any one of the above (1) to (7), when the power of the output signal is set to a minimum value used for operation, an efficiency of the outphasing amplifier may be higher than an efficiency thereof when θ3=180°−θbo and θ4=+θbo are assumed. Thus, the characteristics of the outphasing amplifier can be improved.

(9) In a method of manufacturing an outphasing amplifier according to the present disclosure, the outphasing amplifier includes: a first amplifier amplifying a first signal; a second amplifier amplifying a second signal; and a combiner. The combiner includes: a first node to which the first signal amplified by the first amplifier is input; a second node to which the second signal amplified by the second amplifier is input; a third node combining the first signal and the second signal and outputting a combined signal as an output signal; a first impedance converter having a first end connected to the first node and a second end connected to the third node; a second impedance converter having a first end connected to the second node and a second end connected to the third node; a first open stub having a first end connected to the first node and a second end that is opened, wherein when an outphasing angle when a power of the output signal has a minimum value is θbo, an electrical length of the first open stub converted into a phase at a center frequency of an operating frequency band is 180°−θbo; and a second open stub having a first end connected to the second node and a second end that is opened, wherein an electrical length of the second open stub converted into a phase at the center frequency is +θbo. The method of manufacturing an outphasing amplifier according to the present disclosure includes: preparing the outphasing amplifier; and adjusting a length of the first open stub and a length of the second open stub such that a first impedance viewed from the first amplifier to the first node and a second impedance viewed from the second amplifier to the second node have values at which characteristics of the first amplifier and the second amplifier are improved. Thus, the outphasing amplifier that can be reduced in size can be manufactured.

(10) In the above (9), the adjusting may include adjusting the length of the first open stub and the length of the second open stub such that a difference between the electrical length of the first open stub and 180°−θbo is 0.5° or more and 10° or less and a difference between the electrical length of the second open stub and +θbo is 0.5° or more and 10° or less. Thus, the characteristics of the outphasing amplifier can be improved.

Specific examples of an outphasing amplifier and a method for manufacturing the same according to embodiments of the present disclosure will be described below with reference to the drawings. It should be noted that the present disclosure is not limited to these examples, but is defined by the claims and is intended to include all modifications within the meaning and scope equivalent to the claims.

### First Embodiment

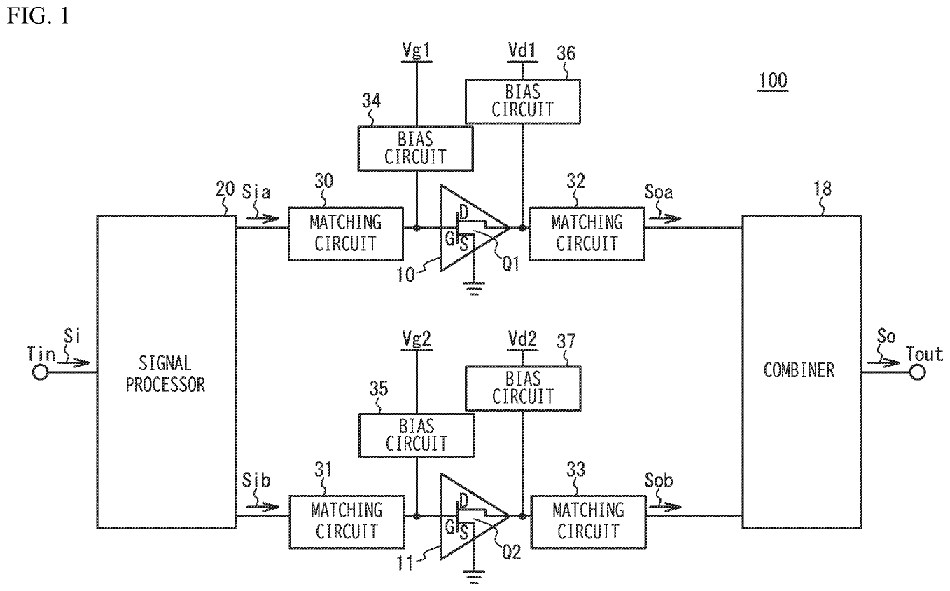

FIG. 1 is a block diagram illustrating an outphasing amplifier according to a first embodiment. As illustrated in FIG. 1, in an outphasing amplifier 100, an amplifier 10 (first amplifier) and an amplifier 11 (second amplifier) are connected in parallel between an input terminal Tin and an output terminal Tout. A high frequency signal is input to the input terminal Tin as an input signal Si. When the outphasing amplifier 100 is used in a mobile communication base station, the frequencies of the high frequency signals are, for example, 0.5 GHz or more and 10 GHz or less. A signal processor 20 processes the input signal Si and outputs the processed signal as two signals Sia (first signal) and Sib (second signal).

The signal Sia is input to the amplifier 10 via a matching circuit 30. The matching circuit 30 matches an output impedance of the signal processor 20 with an input impedance of the amplifier 10. The amplifier 10 amplifies the signal Sia input via the matching circuit 30 and outputs an amplified signal Soa via a matching circuit 32. The signal Soa passed through the matching circuit 32 is input to a combiner 18. The matching circuit 32 matches an output impedance of the amplifier 10 with an input impedance of the combiner 18. A signal Sib is input to the amplifier 11 via a matching circuit 31. The matching circuit 31 matches an output impedance of the signal processor 20 with an input impedance of the amplifier 11. The amplifier 11 amplifies the signal Sib input via the matching circuit 31 and outputs an amplified signal Sob via a matching circuit 33. The signal Sob passed through the matching circuit 33 is input to the combiner 18. The matching circuit 33 matches an output impedance of the amplifier 11 with an input impedance of the combiner 18. The combiner 18 combines the signals Soa and Sob. A combined signal is output from the output terminal Tout as an output signal So.

A bias circuit 34 supplies a bias voltage Vg1 to a gate G of the amplifier 10 and prevents the signal Sia from leaking to a bias terminal. A bias circuit 36 supplies a bias voltage Vd1 to a drain D of the amplifier 10 and prevents the signal Soa amplified by the amplifier 10 from leaking to a bias terminal. A bias circuit 35 supplies a bias voltage Vg2 to a gate G of the amplifier 11 and prevents the signal Sib from leaking to a bias terminal. A bias circuit 37 supplies a bias voltage Vd2 to a drain D of the amplifier 11 and prevents the signal Sob amplified by the amplifier 11 from leaking to a bias terminal.

The amplifiers 10 and 11 include, for example, FETs (Field Effect Transistors) Q1 and Q2, respectively. Sources S of the FETs Q1 and Q2 are grounded, the signals Sia and Sib are input to the gates G via the matching circuits 30 and 31, respectively, and the amplified signals are output from the drains D. The FETs Q1 and the Q2 are, for example, GaN HEMT (Gallium Nitride High Electron Mobility Transistor) or LDMOS (Laterally Diffused Metal Oxide Semiconductor). Each of the amplifiers 10 and 11 may be provided with a multistage FET. The amplifiers 10 and 11 may include transistors other than the FETs.

The matching circuits 30, 31, 32, and 33 are designed so that high frequency characteristics such as drain efficiency are optimized when the amplifiers 10 and 11 output a saturation power, for example. This improves high frequency characteristics such as drain efficiency when the amplifiers 10 and 11 amplify the signals Sia and Sib.

The signal processor 20 is, for example, a Signal Processing Unit, and digitally processes the input signal Si and outputs signals Sia and Sib. The outphasing amplifier 100 outputs the output signal So having an amplitude of the output power corresponding to an amplitude of the input power of the input signal Si. The signal processor 20 sets an outphasing angle of the signals Sia and Sib depending on the amplitude of the input signal Si in order to output an output signal So depending on the amplitude of the input signal Si.

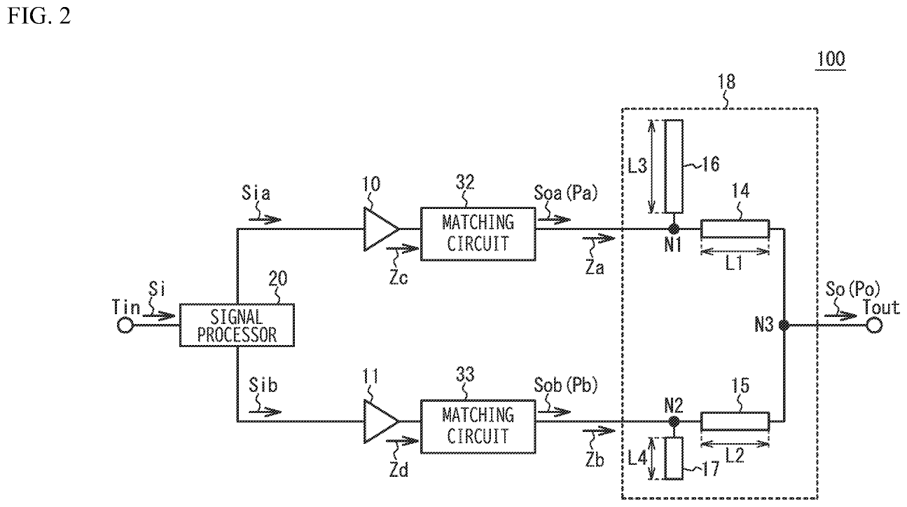

FIG. 2 is a block diagram illustrating the outphasing amplifier according to the first embodiment. In FIG. 2, the matching circuits 30 and 31 and the bias circuits 34, 35, 36 and 37 are not illustrated, and the configuration in the combiner 18 is illustrated. As illustrated in FIG. 2, in the outphasing amplifier 100 according to the first embodiment, the combiner 18 is, for example, a Chireix combiner. The combiner 18 includes transmission lines 14 and 15 and open stubs 16 and 17.

A first end of the transmission line 14 (first transmission line) is electrically connected to a node N1 (first node), and a second end of the transmission line 14 is electrically connected to a node N3 (third node). A first end of the transmission line 15 (second transmission line) is electrically connected to a node N2 (second node), and a second end of the transmission line 15 is electrically connected to the node N3. A first end of the open stub 16 (first open stub) is electrically connected to the node N1, and a second end of the open stub 16 is opened. A first end of the open stub 17 (second open stub) is electrically connected to the node N2, and a second end of the open stub 17 is opened.

The signal Soa input to the node N1 (the first signal amplified by the first amplifier) and the signal Sob input to the node N2 (the second signal amplified by the second amplifier) are combined at the node N3, and the combined signal is output to the output terminal Tout as the signal So of a power Po.

The transmission lines 14 and 15 are impedance converters, and convert the output impedances of the matching circuits 32 and 33 to twice (100Ω) a standard impedance (for example, 50Ω). As a result, an impedance viewed from the node Tout to the node N3 is the standard impedance (50Ω). The electrical lengths of the transmission lines 14 and 15 are L1 and L2, respectively. The electrical lengths L1 and L2 are, for example, λ/4. The “λ” is a wavelength at a center frequency f0 of the operating frequency band of the outphasing amplifier 100. When θ1 and θ2 are electrical lengths obtained by converting the electrical lengths L1 and L2 into phases at the center frequency f0, respectively, “θ1=θ2=90°” is satisfied.

### [Description of Outphasing Operation]

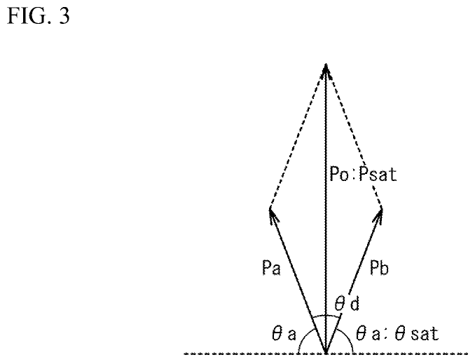

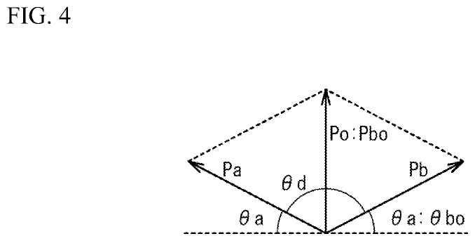

FIGS. 3 and 4 are schematic diagrams illustrating vectors of the output power according to the first embodiment. FIG. 3 corresponds to a case where the power Po of the outphasing amplifier 100 is maximized, and FIG. 4 corresponds to a case where the power Po of the outphasing amplifier 100 is minimized. The output power Po of the maximum value used in operation is referred to as the saturation power and is represented by a power Psat. The output power Po of the minimum value used in operation is referred to as the back-off power and represented by a power Pbo.

In FIGS. 3 and 4, a power Pa is a vector of the power of the signal Soa at the node N1, and a power Pb is a vector of the power of the signal Sob at the node N2. The powers Pa and Pb are, for example, saturation powers of the amplifiers 10 and 11, respectively. A combined vector of the powers Pa and Pb is the output power Po output from the output terminal Tout. Assuming that the outphasing angle is θa and a phase difference between the powers Pa and Pa is θd, “2×θa+θd=180°” is satisfied. That is, when the phase of the power P1 is rotated by +θa and the phase of the power P2 is rotated by −θa from the state in which the phase difference θd is 180°, the angle θa is referred to as the outphasing angle.

As illustrated in FIG. 3, when the output power Po is increased, the outphasing angle θa is increased to be closer to 90°. As illustrated in FIG. 4, when the output power Po is decreased, the outphasing angle θ a is decreased to be closer to 0°. In the combiner 18 which is the Chireix combiner, when the outphasing angle is set to around 90° and around 0°, the reactance components of the impedances viewed from the nodes No1 and No2 to the combiner 18 become large, and load impedances Za1 and Za2 of the amplifiers 10 and 11 deviate from the optimum values. Therefore, the outphasing angle θa is used in a range between an angle θsat smaller than 90° and an angle θbo larger than 0°. That is, in FIG. 3, the outphasing angle θa when the output power Po is the power Psat is the angle θsat. The angle θsat is a maximum outphasing angle θa used in the operation of the outphasing amplifier 100. In FIG. 4, the outphasing angle θa when the output power Po is the power Pbo is the angle θbo. The angle θbo is a minimum outphasing angle θa used in the operation of outphasing amplifier 100. The angle θsat is, for example, 70°, and the angle θbo is, for example, 20°.

The outphasing angle θa is controlled by the signal processor 20. For example, when the output power Po is increased, the signal processor 20 increases the outphasing angle θa of the signals Sia and Sib. When the output power Po is decreased, the signal processor 20 decreases the outphasing angle θa of the signals Sia and Sib. The outphasing angle θa of the signals Sia and Sib is substantially the same as the outphasing angle θa of the signals Soa and Sob obtained by amplifying the signals Sia and Sib.

Therefore, the signal processor 20 can change the outphasing angle θa of the signals Sia and Sib by changing the outphasing angle θa. Thus, the signal processor 20 changes the outphasing angle θa of the signals Sia and Sib based on the input signal Si, and outputs the signals Sia and Sib with the changed outphasing angle θa to the amplifiers 10 and 11, respectively.

### [Description of Chireix Combiner]

In order to describe the functions of the open stubs 16 and 17, a first comparative example will be described. In the outphasing amplifier according to the first comparative example, the open stubs 16 and 17 are not provided in the combiner 18. The combiner of the first comparative example is not the Chireix combiner.

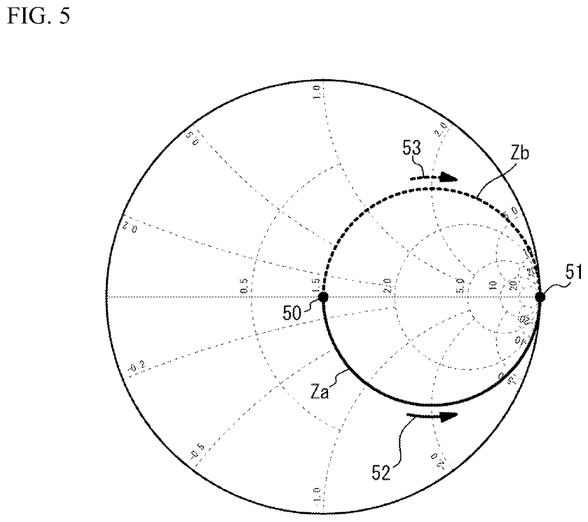

FIG. 5 is a Smith chart illustrating impedances in the first comparative example, and is a Smith chart illustrating impedances Za and Zb viewed from the matching circuits 32 and 33 to the combiner 18. As illustrated in FIG. 5A, a point 50 indicates a case where the outphasing angle θa is 0°, and a point 51 indicates a case where the outphasing angle θa is 90°. When the outphasing angle θa changes from 0° to 90°, the impedance Za moves along the locus of a lower half of an arc from the point 50 to the point 51 as indicated by an arrow 52. The impedance Zb moves along the locus of an upper half of the arc from the point 50 to the point 51 as indicated by an arrow 53.

When the impedances Za and Zb are real numbers (e.g., twice the standard impedance), the matching circuits 32 and 33 convert the output impedances of the amplifiers 10 and 11 so that the high frequency characteristics of the amplifiers 10 and 11 are optimized (e.g., drain efficiency is maximum). This results in the maximum characteristics of the amplifiers 10 and 11 when the impedances Za and Zb are real numbers in FIG. 5. At the points 50 and 51, the impedances Za and Zb are real numbers. The range of the outphasing angle θa is a range between θsat in FIG. 3 and θbo in FIG. 4. In this range, the reactance components (imaginary components) of the impedances Za and Zb are large, and the load impedances of the amplifiers 10 and 11 deviate from the optimum values. In addition, reactive power increases.

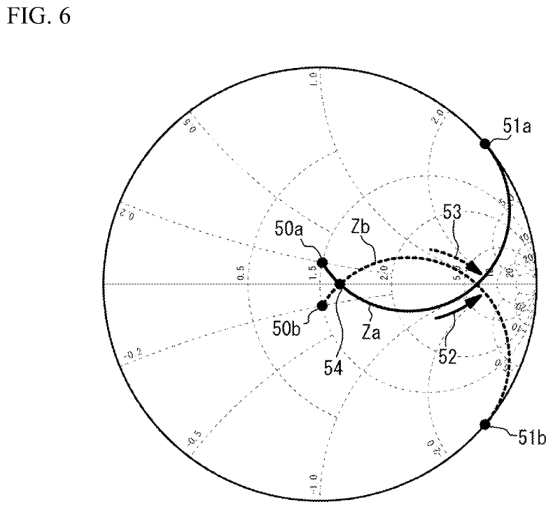

FIG. 6 is a Smith chart illustrating impedances in the first embodiment, and is a Smith chart illustrating the impedances Za and Zb viewed from the matching circuits 32 and 33 to the combiner 18. An electrical length L3 of the open stub 16 is an electrical length having a capacitive property, and an electrical length L4 of the open stub 17 is an electrical length having an inductive property. That is, the open stub 16 is made longer than 2λ and shorter than 4λ. The open stub 17 is made longer than 0λ and shorter than 2λ. When the electrical lengths L3 and L4 are expressed by using electrical lengths θ3 and θ4 converted to the phases at the frequency f0, respectively, the electrical length θ3 is larger than 90° and smaller than 180°. The electrical length θ4 is larger than 0° and smaller than 90°.

As illustrated in FIG. 6, by providing the open stub 16, the reactance component of the impedance Za shifts in a positive direction and rotates in a counterclockwise direction as compared with FIG. 5 of the first comparative example in a state where the entire arc shape is maintained on the Smith chart of the impedance. By providing the open stub 17, the reactance component of the impedance Zb shifts in a negative direction and rotates in a clockwise direction as compared with the first comparative example in a state where the entire arc shape is maintained on the Smith chart of the impedance. The reactance components of the impedance Za at the point 50a when the outphasing angle θa is 0° and at the point 51a when the outphasing angle θa is 90° are positive. The reactance components of the impedance Zb at the point 50b when the outphasing angle θa is 0° and at the point 51b when the outphasing angle θa is 90° are negative.

In the outphasing amplifier, characteristics such as efficiency are improved when the output power Po is the back-off power Pbo. Therefore, the electrical length θ3 of the open stub 16 is set to 180°−θbo, and the electrical length θ4 of the open stub 17 is set to +θbo. As a result, the impedances Za and Zb when the outphasing angle θa is the angle θbo are represented by a point 54 on the real axis. Thus, when the output power Po is the back-off power Pbo, characteristics such as efficiency can be improved. The impedances Za and Zb when the outphasing angle θa is the angle θsat are not necessarily on the real axis, but are closer to the real axis than those in FIG. 5. When the outphasing angle θa is in the range between the angle θbo and the angle θsat, the impedances Za and Zb are closer to the real axis as compared with FIG. 5 and the reactance components are reduced. Therefore, the load impedances of the amplifiers 10 and 11 are close to the optimum values. Thereby, high frequency characteristics such as drain efficiency are improved.

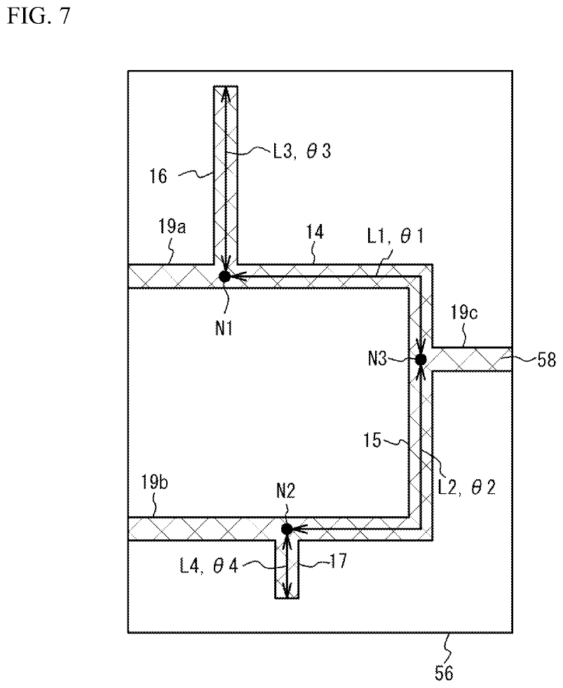

FIG. 7 is a plan view of the Chireix combiner according to the first embodiment. As illustrated in FIG. 7, a conductor pattern 58 is provided on an upper surface of a dielectric layer 56. A conductor layer to which a reference potential is supplied is provided on a lower surface of the dielectric layer 56. A transmission line 19a is a line between the matching circuit 32 and the node N1. A transmission line 19b is a line between the matching circuit 33 and the node N2. A transmission line 19c is a line between the node N3 and the output terminal Tout. The transmission lines 14, 15, 19a to 19c, and the open stubs 16 and 17 are formed as microstrip lines by the conductor pattern 58 and the conductor layer on the lower surface. The dielectric layer 56 is a dielectric substrate made of, for example, resin such as FR-4 (Flame Retardant Type 4) or ceramic. The conductor pattern 58 and the conductor layer on the lower surface of the dielectric layer 56 are, for example, a metal layer such as a copper layer or a gold layer.

The node N1 corresponds to a point at which the center lines of the transmission lines 14 and 19a, and the open stub 16 intersect. The node N2 corresponds to a point at which the center lines of the transmission lines 15 and 19b, and the open stub 17 intersect. The node N3 corresponds to a point where the center lines of the transmission lines 14, 15 and 19c intersect. The electrical lengths L1 and θ1 correspond to the length of the center line of the transmission line 14 between the points corresponding to the nodes N1 and N3. The electrical lengths L2 and θ2 correspond to the length of the center line of the transmission line 15 between the points corresponding to the nodes N2 and N3. The electrical lengths L3 and θ3 correspond to the length of the center line of the open stub 16 between the node N1 and the tip of the open stub 16. The electrical lengths L4 and θ4 correspond to the length of the center line of the open stub 17 between the node N2 and the tip of the open stub 17. The center line is a line connecting middle points of the line in a direction orthogonal to the direction in which the line extends.

The electrical lengths L1 and θ1 to L4 and θ4 can be calculated from the physical lengths using a relative dielectric constant ε0 of the dielectric layer 56. For example, the wavelength λ of the fundamental wave is expressed by “λ=c/f0/√ε0”, where c is the speed of light. The wavelength λ of the microstrip transmission line may be calculated by a known method. Thus, the electrical length can be calculated from the physical length.

### [Description of Second Comparative Example]

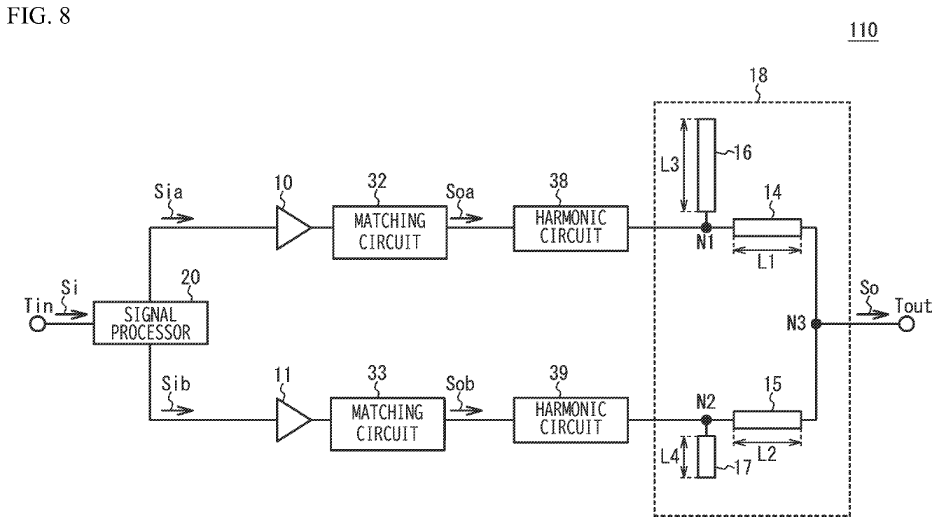

FIG. 8 is a circuit diagram illustrating an outphasing amplifier according to a second comparative example. As illustrated in FIG. 8, in an outphasing amplifier 110 of the second comparative example, a harmonic circuit 38 is connected between the matching circuit 32 and the node N1, and a harmonic circuit 39 is provided between the matching circuit 33 and the node N2. The harmonic circuit 38 and the harmonic circuit 39 are circuits that process harmonics (for example, a second harmonic or a third harmonic) of the fundamental wave of the frequency f0. The harmonic circuits 38 and 39 are, for example, series resonators that are shunt-connected to the signal line and resonate at harmonic frequencies. This allows the harmonic circuits 38 and 39 to reflect the harmonics transmitted through the signal line and to suppress the harmonics from being output from the output terminals and degrading the characteristics of the outphasing amplifier 110, such as efficiency. However, when the harmonic circuits 38 and 39 are provided, the outphasing amplifier 110 increases in size. Further, when the harmonic circuits 38 and 39 are provided, the loss increases due to the insertion loss.

### [Design Method of Outphasing Amplifier of First Embodiment]

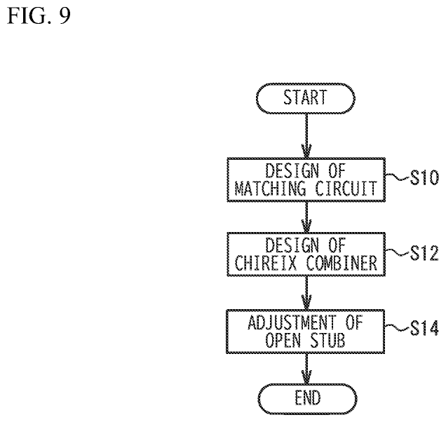

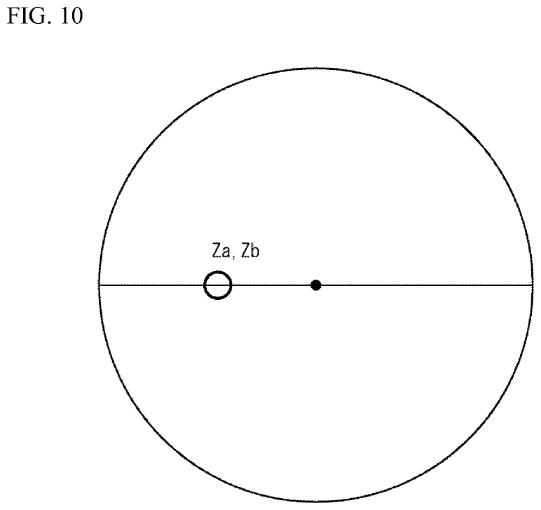

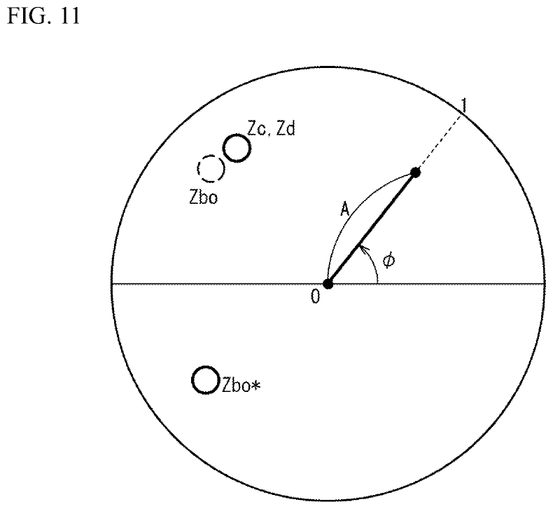

FIG. 9 is a flowchart illustrating a method of designing an outphasing amplifier according to the first embodiment. FIG. 10 is a Smith chart illustrating impedances Za and Zb in the fundamental wave. FIG. 11 is a Smith chart illustrating impedances Zc and Zd in the fundamental wave. In FIGS. 10 and 11, a straight line corresponds to a real axis.

As illustrated in FIG. 2, the impedance Za is an impedance viewed from the matching circuit 32 to the combiner 18. The impedance Zb is an impedance viewed from the matching circuit 33 to the combiner 18. The impedance Zc is an impedance viewed from the amplifier 10 to the matching circuit 32. The impedance Zd is an impedance viewed from the amplifier 11 to the matching circuit 33. It should be noted that the impedances Za to Zd in FIGS. 10 and 11 are virtual impedances for explaining the design method.

The impedances Za to Zd in FIGS. 10 and 11 indicate the impedances Za to Zd when the outphasing angle θa is the angle θbo, for example. When the Smith chart is illustrated in consideration of the phase difference (outphasing angle θa) between the signals Soa and Sob, the positions of the impedances Za to Zd rotate on the Smith chart as illustrated in FIG. 6, which complicates the chart. Therefore, in FIGS. 10 and 11, the Smith chart is illustrated without considering the rotation caused by the outphasing angle θa.

As illustrated in FIG. 9, in step S10, matching circuits 32 and 33 are designed at the center frequency f0 (e.g., 3.5 GHZ) of the operating frequency band of the outphasing amplifier 100 as the fundamental wave. By performing load pull measurement on the amplifiers 10 and 11, the load impedance at which the characteristics such as the efficiency of the amplifiers 10 and 11 become the highest in the fundamental wave is measured. Zbo* in FIG. 11 is impedance (impedance viewed from the load-pull measuring device to the amplifiers 10 and 11) at which the characteristics such as the efficiency of the amplifiers 10 and 11 are the highest in the fundamental wave. The matching circuits 32 and 33 are designed to convert impedances Za and Zb of FIG. 10 to Zbo, which is a complex conjugate of Zbo* of FIG. 11.

Next, in step S12 of FIG. 9, the Chireix combiner is designed as the combiner 18 in the fundamental wave. In the combiner 18, each of the electrical lengths θ1 and θ2 of the transmission lines 14 and 15 is 90°. The electrical length θ3 of the open stub 16 is 180°−θbo. The electrical length θ4 of the open stub 17 is θbo. The matching circuits 32 and 33 are designed so that the characteristics (e.g., efficiency and output power) of the outphasing amplifier 100 are desired characteristics at the center frequency f0 (e.g., 3.5 GHZ) of the operating frequency band of the outphasing amplifier 100. Thus, the Chireix combiner is designed as the matching circuits 32 and 33 and the combiner 18 so that the outphasing amplifier 100 has the desired characteristics at the frequency f0. The order of steps S10 and S12 may be reversed.

As illustrated in FIG. 10, the combiner 18 performs impedance conversion on the load resistance of the output terminal Tout. Thus, the impedances Za and Zb when the outphasing angle θa in the fundamental wave is θbo are located on the real axis.

The matching circuits 32 and 33 are not designed in consideration of the harmonics. This is because each of the matching circuits 32 and 33 includes a plurality of capacitors, inductors, and transmission lines, and it is very complicated to design the matching circuits 32 and 33 in consideration of the fundamental wave and the harmonics. The impedances Zc and Zd deviate from the target impedance Zbo due to the effect of the harmonics and the effect of coupling the amplifiers 10 and 11 via the combiner 18.

Next, in step S14 of FIG. 9, the impedances Zc and Zd are adjusted to the target impedance Zbo by adjusting the electrical length L3 of the open stub 16 and the electrical length L4 of the open stub 17. The electrical lengths L3 and L4 of the open stubs 16 and 17 are finely adjusted using a trimming technique such as laser trimming.

As an example of the adjustment, the electrical length L4 is adjusted so that the impedance Zc becomes the target impedance Zbo, and the electrical length L3 is adjusted so that the impedance Zd becomes the target impedance Zbo. As another example, the electrical length L3 is adjusted so that the impedance Zc becomes the target impedance Zbo, and the electrical length L4 is adjusted so that the impedance Zd becomes the target impedance Zbo.

The electrical lengths L3 and L4 may be adjusted such that the harmonic (e.g., a second harmonic) is reflected at the node N1 and the harmonic is reflected at the node N2.

When the electrical lengths L3 and L4 are adjusted, the characteristics of the combiner 18 in the fundamental wave also change. However, the wavelength of the harmonic is shorter than the wavelength of the fundamental wave. For this reason, when the electrical lengths L3 and L4 are slightly changed, the characteristics of the harmonic waves of the open stubs 16 and 17 are largely changed, but the characteristics of the fundamental waves of the open stubs 16 and 17 are not largely changed. Therefore, the change in the characteristics of the combiner 18 in the fundamental wave is very small.

### [Comparison Between First Embodiment and Second Comparative Example]

As an example, the measurement results of the outphasing amplifier will be described in the case where the harmonic circuit is provided as in the second comparative example and in the case where the electrical lengths L3 and L4 of the open stubs 16 and 17 are adjusted as in the first embodiment. The conditions common to the second comparative example and the first embodiment are as follows; f0=3.5 GHZ, Psat=48 dBm, θsat=70° and θbo=20°. As illustrated in FIG. 11, the impedance is represented by polar coordinates of the Smith chart. The polar coordinates are represented by a radius vector A and an angle φ with a center of 0 and a perimeter of 1.

In both of the second comparative example and the first embodiment, when the outphasing angle θ a is the angle θ bo, the impedances Zc and Zd in the fundamental wave are A=0.9 and φ=160°. Next, the electrical length θ3 of the open stub 16 and the electrical length θ4 of the open stub 17 were set as follows. In the second comparative example, the electrical length θ3 was set to 160° and the electrical length θ4 was set to 20°. In the first embodiment, the electrical length θ3 was set to 158° and the electrical length θ4 was set to 18°. Thus, in the first embodiment, the electrical lengths θ3 and θ4 were shortened by 2° as compared with the second comparative example. In the second comparative example, the impedance of the matching circuit 32 viewed from the amplifier 10 in the second harmonic is A≈1.0 and φ=160°. In the first embodiment, the impedance of the matching circuit 32 viewed from the amplifier 10 in the second harmonic is A≈1.0 and φ=163°. Thus, the impedance φ in the second harmonic in the first embodiment was slightly larger than that in the second comparative example.

The drain efficiency at the back-off power Pbo in the outphasing amplifier at this time was improved by 2% in the first embodiment compared with the second comparative example. This is because the second harmonic is easily reflected at the nodes N1 and N2 by the open stub 16 and the open stub 17, and the insertion loss is reduced by not providing the harmonic circuits 38 and 39.

In the first embodiment, the transmission line 14 is a first impedance converter, and the transmission line 15 is a second impedance converter. The electrical length θ3 of the open stub 16 is made different from (180°−θbo). The electrical length θ4 of the open stub 17 is made different from +θbo. This makes it possible to improve characteristics such as efficiency of the outphasing amplifier 100 without providing the harmonic circuits 38 and 39 as in the second comparative example. Therefore, the outphasing amplifier 100 can be reduced in size.

For example, in order to adjust the electrical length L1 of the transmission line 14 and the electrical length L2 of the transmission line 15, the pattern of the conductor pattern 58 in FIG. 7 is changed, and the entire combiner 18 is replaced. Thus, it is difficult to adjust the characteristics of the outphasing amplifier 100 using elements other than the open stubs 16 and 17. In the first embodiment, since the open stubs 16 and 17 are used, it is easy to adjust the electrical lengths θ3 and θ4.

The fact that both electrical lengths θ3 and θ4 of the open stub 16 differ from both (180°−θbo) and +θbo means that the former differs from the latter even when a manufacturing error is taken into account. When the electrical lengths θ3 and θ4 can be set with an accuracy of, for example, about 0.5°, the electrical lengths θ3 and θ4 are not included in either the range within (180°−θbo)+0.5° or the range within +θbo+0.5°.

In the combiner 18 of the second comparative example, the electrical lengths θ3 and θ4 are (180°−θbo) and θbo, respectively, to the extent of the manufacturing error. The manufacturing error of the electrical lengths θ3 and θ4 is less than 0.5°. Thus, an absolute value of a difference between the electrical length θ3 and (180°−θbo) may be 0.5° or more, 0.7° or more, 1.0° or more, or 2.0° or more. An absolute value of a difference between the electrical lengths θ4 and +θbo may be 0.5° or more, 0.7° or more, 1.0° or more, or 2.0° or more. Thus, the characteristics of the outphasing amplifier 100 can be improved.

When the difference between the electrical length θ3 and (180°−θbo) and the difference between the electrical length θ4 and +θbo are too large, the function of the combiner 18 of the fundamental wave is reduced. From this viewpoint, the absolute value of the difference between the electrical length θ3 and (180°−θbo) may be 10° or less, 5° or less, or 3° or less. The absolute value of the difference between θ4 and +θbo may be 10° or less, may be 5° or less, or 3° or less.

When the electrical length θ3 is made different from (180°−θbo) and the electrical length θ4 is made different from +θbo, in FIG. 6, the outphasing angle θa at which the impedances Za and Zb are on the real axis deviates from θbo. The impedances Za and Zb are preferably on the real axis at the same outphasing angle θa. If a sign indicating whether θ3−(180°−θbo) is positive or negative is different from a sign indicating whether θ4−θbo is positive or negative, the impedances Za and Zb rotate in the same direction in FIG. 6. Therefore, the sign of θ3−(180°−θbo) and the sign of θ4−θbo may be the same as each other. Thus, the characteristics of the outphasing amplifier 100 can be improved.

When the sign of θ3−(180°−θbo) and the sign of θ4−θbo are both positive, the impedances Za and Zb are on the real axis in FIG. 6 when the outphasing angle θa is smaller than θbo. The outphasing angle θa used in the outphasing amplifier 100 is θbo or more and θsat or less, and an outphasing angle θa smaller than θbo is not used. Therefore, in order for the impedances Za and Zb to be on the real axis at the outphasing angle θa actually used, both of the sign of θ3−(180°−θbo) and the sign of θ4−θbo may be negative.

Further, when the absolute value of the difference between θ3−(180°−θbo) and θ4−θbo is large, the outphasing angles θa at which the impedances Za and Zb are on the real axis, respectively, differ from each other. From this viewpoint, the absolute value of the difference between θ3−(180°−θbo) and θ4−θbo may be 1° or less, 0.5° or less, or substantially 0°. Thus, the characteristics of the outphasing amplifier 100 can be improved.

The transmission lines 14 and 15 are impedance converters that convert an impedance at a certain position on the real axis in the Smith chart into an impedance at a different position on the real axis. Therefore, the electrical length L1 of the transmission line 14 (first transmission line) and the electrical length L2 of the transmission line 15 (second transmission line) are ¼ of the wavelength of the fundamental wave. That is, the electrical lengths θ1 and θ2 are 90°. This allows the combiner 18 to function as the Chireix combiner. The electrical lengths L1 and L2 need not be exactly ¼ of the wavelength, as long as they function as impedance converters. For example, each of the electrical lengths θ1 and θ2 may be 80° or more and 100° or less, 85° or more and 95° or less, or 89° or more and 91° or less.

As illustrated in FIG. 7, the transmission line 14, the transmission line 15, the open stub 16, and the open stub 17 are formed by the dielectric layer 56 and the conductor pattern 58 provided on the dielectric layer 56. Thus, the electrical lengths θ3 and θ4 of the open stub 16 and the open stub 17 can be easily adjusted.

The matching circuit 32 (first matching circuit) is connected between the amplifier 10 and the node N1, and the matching circuit 33 (second matching circuit) is connected between the amplifier 11 and the node N2. This makes it possible to match the impedances Za and Zb with the impedances Zc and Zd at which the amplifiers 10 and 11 operate optimally.

When the output power Po is the power Pbo set to the minimum value, the efficiency such as the drain efficiency of the outphasing amplifier 100 is higher than the efficiency such as the drain efficiency of the outphasing amplifier 110 of the second comparative example assuming that θ3=180°−θbo and θ4=+θbo. The efficiency of the outphasing amplifier 100 is higher than the efficiency of the outphasing amplifier 110 of the second comparative example by 0.1% or more, 0.5% or more, or 1% or more.

### MANUFACTURING METHOD OF OUTPHASING AMPLIFIER OF FIRST EMBODIMENT

Although in step S14 in FIG. 9, the electrical lengths of the open stubs 16 and 17 are adjusted when designing the outphasing amplifier, step S14 may be performed in the manufacturing process.

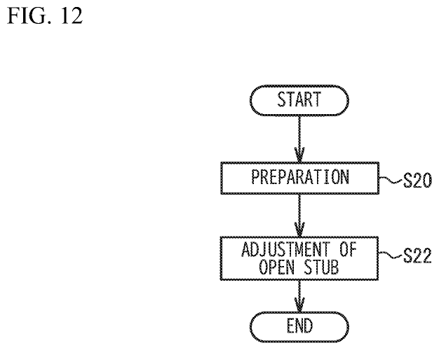

FIG. 12 is a diagram illustrating a method of manufacturing the outphasing amplifier according to the first embodiment. As illustrated in FIG. 12, first, the outphasing amplifier having the open stub 16 whose electrical length θ3 is 180°−θbo and the open stub 17 whose electrical length θ4 is +θbo is prepared (step S20). Thereafter, the electrical lengths θ3 and θ4 are adjusted so that the impedance Zc or Za viewed from the amplifier 10 to the node N1 and the impedance Zd or Zb viewed from the amplifier 11 to the node N2 have desired values (for example, values at which the characteristics of the amplifiers 10 and 11 are improved) (step S22). As a result, it is possible to manufacture the outphasing amplifier which can be reduced in size and have improved characteristics.

The embodiments disclosed here should be considered illustrative in all respects and not restrictive. The present disclosure is not limited to the specific embodiments described above, but various variations and changes are possible within the scope of the gist of the present disclosure as described in the claims.

What is claimed is:

1. An outphasing amplifier comprising:
a first amplifier amplifying a first signal;
a second amplifier amplifying a second signal; and
a combiner;
wherein the combiner includes:
a first node to which the first signal amplified by the first amplifier is input;
a second node to which the second signal amplified by the second amplifier is input;
a third node combining the first signal and the second signal and outputting a combined signal as an output signal;
a first impedance converter having a first end connected to the first node and a second end connected to the third node;
a second impedance converter having a first end connected to the second node and a second end connected to the third node;
a first open stub having a first end connected to the first node and a second end that is opened, wherein when an electrical length of the first open stub converted into a phase at a center frequency of an operating frequency band is θ3, and an outphasing angle when a power of the output signal has a minimum value is θbo, θ3 is different from any of 180°−θbo and +θbo; and
a second open stub having a first end connected to the second node and a second end that is opened, wherein when an electrical length of the second open stub converted into a phase at the center frequency is θ4, θ4 is different from any of 180°−θbo and +θbo.

2. The outphasing amplifier according to claim 1, wherein
an absolute value of a difference between θ3 and 180°−θbo is 0.5° or more and 10° or less, and
an absolute value of a difference between θ4 and +θbo is 0.5° or more and 10° or less.

3. The outphasing amplifier according to claim 2, wherein
a sign of θ3−(180°−θbo) and a sign of θ4−θbo are the same as each other.

4. The outphasing amplifier according to claim 3, wherein
an absolute value of a difference between θ3−(180°−θbo) and θ2−θbo is 1° or less.

5. The outphasing amplifier according to claim 1, wherein
the first impedance converter is a first transmission line whose electrical length is ¼ of a wavelength of the center frequency, and
the second impedance converter is a second transmission line whose electrical length is ¼ of a wavelength of the center frequency.

6. The outphasing amplifier according to claim 5, wherein
the first transmission line, the second transmission line, the first open stub, and the second open stub are formed by a dielectric layer and a conductor pattern provided on the dielectric layer.

7. The outphasing amplifier according to claim 1, further comprising:
a first matching circuit connected between the first amplifier and the first node; and
a second matching circuit connected between the second amplifier and the second node.

8. The outphasing amplifier according to claim 1, wherein
when the power of the output signal is set to a minimum value used for operation, an efficiency of the outphasing amplifier is higher than an efficiency thereof when θ3=180°−θbo and θ4=+θbo are assumed.

9. A method of manufacturing an outphasing amplifier, the outphasing amplifier including:
a first amplifier amplifying a first signal;
a second amplifier amplifying a second signal; and
a combiner;
wherein the combiner includes:
a first node to which the first signal amplified by the first amplifier is input;
a second node to which the second signal amplified by the second amplifier is input;
a third node combining the first signal and the second signal and outputting a combined signal as an output signal;
a first impedance converter having a first end connected to the first node and a second end connected to the third node;
a second impedance converter having a first end connected to the second node and a second end connected to the third node;
a first open stub having a first end connected to the first node and a second end that is opened, wherein when an outphasing angle when a power of the output signal has a minimum value is θbo, an electrical length of the first open stub converted into a phase at a center frequency of an operating frequency band is 180°−θbo; and
a second open stub having a first end connected to the second node and a second end that is opened, wherein an electrical length of the second open stub converted into a phase at the center frequency is +θbo;
the method comprising:
preparing the outphasing amplifier; and
adjusting a length of the first open stub and a length of the second open stub such that a first impedance viewed from the first amplifier to the first node and a second impedance viewed from the second amplifier to the second node have values at which characteristics of the first amplifier and the second amplifier are improved.

10. The method of manufacturing the outphasing amplifier according to claim 9, wherein
the adjusting includes adjusting the length of the first open stub and the length of the second open stub such that a difference between the electrical length of the first open stub and 180°−θbo is 0.5° or more and 10° or less and a difference between the electrical length of the second open stub and +θbo is 0.5° or more and 10° or less.
